(19) United States
(12) Patent Application Publication
(10) Pub. No.: US 2014/0060896 A1
(43) Pub. Date: Mar. 6, 2014

(54) PRINTED CIRCUIT BOARD

(71) Applicant: SAMSUNG ELECTRO-MECHANICS CO., LTD., Suwon (KR)

(72) Inventors: Gil Yong SHIN, Suwon (KR); Seung Lak Kim, Suwon (KR); Kyoung Ro Yoon, Suwon (KR)

(73) Assignee: SAMSUNG ELECTRO-MECHANICS CO., LTD., Suwon-si (KR)

(21) Appl. No.: 13/827,429

(22) Filed: Mar. 14, 2013

(30) Foreign Application Priority Data
Sep. 4, 2012 (KR) 10-2012-0097683

(51) Int. Cl. H05K 1/02

(52) U.S. Cl. CPC H05K 1/0201
USPC 174/252

(57) ABSTRACT

Disclosed herein is a printed circuit board, including: an insulating layer; a circuit layer formed on one surface of the insulating layer; and a via electrode penetrating through the insulating layer and being connected with the circuit layer, wherein the circuit layer is formed in a structure where different kinds of metal layers having different thermal conductivities are laminated.

### CROSS REFERENCE(S) TO RELATED APPLICATIONS

This application claims the benefit under 35 U.S.C. Section 119 of Korean Patent Application Serial No. 10-2012-0097683, entitled “Printed Circuit Board” filed on Sep. 4, 2012, which is hereby incorporated by reference in its entirety into this application.

### BACKGROUND OF THE INVENTION

1. Technical Field

The present invention relates to a printed circuit board, and more particularly to a printed circuit board capable of reducing the defect rate of products.

2. Description of the Related Art

A printed circuit board (PCB) is manufactured by printing circuit line patterns of a conductive material such as copper on an electrically insulated substrate, and is referred to as a board immediately before electronic components are mounted thereon. That is, the printed circuit board means a circuit board where mount positions of respective components are defined and circuit patterns for component connection are printed and fixed on a surface of the flat plate, in order to concentrate and mount several kinds of electronic devices on the flat plate.

This printed circuit board is consolidating its position as one of electronic components together with the development of semiconductors and electronic devices, and is widely used as a component for realizing circuits of all electric and electronic devices including from various kinds of electric and electronic products, such as, radio, television, PCS, and the like, to computer and high-tech electronic equipment. Recently, as technology in this field makes remarkable progress, the printed circuit board requires higher degree of quality, and thus, densification thereof is rapidly occurring.

The printed circuit boards are generally classified into a single-layer printed circuit board and a build-up board having multiple layers of circuit patterns, that is, a multi-layer printed circuit board. The multi-layer printed circuit board basically includes circuit patterns respectively formed on upper and lower surfaces of an insulting layer and solder resist layers for protecting the circuit patterns. Also, a via hole for interlayer electric connection is provided, and this via hole may be formed to have a very fine diameter by using a laser instead of the existing mechanic drilling.

Meanwhile, following the trend of development of the printed circuit board toward the small form factor, technologies for decreasing the overall thickness of the printed circuit board to a predetermined height (for example, 100 μm) are required.

As one of the technologies, there has been an effort of decreasing the thickness of an insulating layer (for example, prepreg) between the circuit patterns. However, when the thickness of the insulating layer is small, the overall coefficient of thermal expansion (CTE) of the printed circuit board is high, and thus interlayer delamination occurs, resulting in warpage of the board, with the result that the binding between a semiconductor chip and the printed circuit board may be defective.

In another different way, the thickness of the solder resist layer of protecting the outermost layer circuit pattern may be lowered. In this case, it is apprehended that the outer layer circuit pattern may be exposed to the outside and products may become defective since constituent fillers of the solder resist layer remains.

In this connection, Korean Patent Laid-Open Publication No. 10-2007-0099360 (hereafter, related art document) discloses a method for manufacturing a light, thin, short, and small type printed circuit board by applying pressure to a surface of a surface protection layer (solder resist layer) to improve flatness.

Specifically, the method includes forming a pad for connecting a portion of the circuit pattern with a semiconductor chip by selectively irradiating light to the surface protection layer. Here, the irradiation of light is performed by using the foregoing laser, and the printed circuit board shown in the related art document does not include a circuit pattern having durability against the heat generated due to irradiation of laser light, and thus the circuit pattern is at a high risk of being penetrated by laser irradiation.

In particular, in the case where the circuit pattern is constituted of copper (Cu) having high thermal conductivity and the circuit pattern is thinly plated in order to decrease the thickness of the printed circuit board, the circuit pattern is at a higher risk of being penetrated by laser irradiation.

### RELATED ART DOCUMENT

### Patent Document

(Patent Document 1) Korean Patent Laid-Open Publication 10-2007-0099360

### SUMMARY OF THE INVENTION

An object of the present invention is to provide a printed circuit board including a circuit layer having durability against the heat generated at the time of irradiation of a laser light.

According to one exemplary embodiment of the present invention, there is provided a printed circuit board, including: an insulating layer; a circuit layer formed on one surface of the insulating layer; and a via electrode penetrating through the insulating layer and being connected with the circuit layer, wherein the circuit layer is formed in a structure where different kinds of metal layers having different thermal conductivities are laminated.

The circuit layer may be composed of a first metal layer and a second metal layer, the second metal layer having lower thermal conductivity than the first metal layer.

The first metal layer may be formed of copper (Cu) and the second metal layer may be formed of a metal selected from the group consisting of gold (Au), platinum (Pt), palladium (Pd), zinc (Zn), tin (Sn), indium (In), aluminum (Al), nickel (Ni), and an alloy thereof.

The circuit layer may have a thickness of 10 to 12 μm.

The printed circuit board may further include an outer layer circuit pattern formed on the other surface of the insulating layer and electrically connected with the circuit layer through the via electrode.

The printed circuit board may further include: a build-up insulating layer covering the circuit layer; and another via electrode penetrating through the build-up insulating layer and being connected with the circuit layer.

The circuit layer may be composed of first metal layers at upper and lower layers and a second metal layer positioned between the first metal layers at upper and lower layers, the second metal layer having lower thermal conductivity than the first metal layer.

According to another exemplary embodiment of the present invention, there is provided a printed circuit board, including; a core insulating layer; a circuit layer formed on one surface or both surfaces of the core insulating layer; an insulating layer covering the circuit layer; and a via electrode penetrating through the insulating layer and being connected with the circuit layer, wherein the circuit layer is formed in a structure where different kinds of metal layers having different thermal conductivities are laminated.

The circuit layer may be composed of a first metal layer and a second metal layer, the second metal layer having lower thermal conductivity than the first metal layer.

The second metal layer may be positioned above the first metal layer based on a lamination direction thereof.

The circuit layer may be composed of first metal layers at upper and lower layers and a second metal layer positioned between the first metal layers at upper and lower layers, the second metal layer having lower thermal conductivity than the first metal layer.

### BRIEF DESCRIPTION OF THE DRAWINGS

FIG. 1 is a cross-sectional view of a printed circuit board according to the present invention;

FIG. 2 is a view showing a state where a first metal layer in FIG. 1 is damaged by irradiation of laser;

FIG. 3 is a cross-sectional view of a printed circuit board to which another type of circuit layer is applied;

FIG. 4 is a view showing a state where a first metal layer in FIG. 3 is damaged by irradiation of laser;

FIG. 5 is a cross-sectional view of a printed circuit board according to another exemplary embodiment of the present invention, to which a first type of circuit layer is applied;

FIG. 6 is a cross-sectional view of a printed circuit board according to another exemplary embodiment of the present invention, to which a second type circuit layer is applied; and

FIG. 7 is a view showing a state where a first metal layer in FIG. 6 is damaged by irradiation of laser.

### DESCRIPTION OF THE PREFERRED EMBODIMENTS

Various advantages and features of the present invention and methods accomplishing thereof will become apparent from the following description of embodiments with reference to the accompanying drawings. However, the present invention may be modified in many different forms and it should not be limited to the exemplary embodiments set forth herein. Rather, these exemplary embodiments may be provided so that this disclosure will be thorough and complete, and will fully convey the scope of the invention to those skilled in the art. Like reference numerals in the drawings denote like elements.

Terms used in the present specification are for explaining the exemplary embodiments rather than limiting the present invention. In the specification, a singular type may also be used as a plural type unless stated specifically. The word “comprise” and variations such as “comprises” or “comprising,” will be understood to imply the inclusion of stated constituents, steps, operations and/or elements but not the exclusion of any other constituents, steps, operations and/or elements.

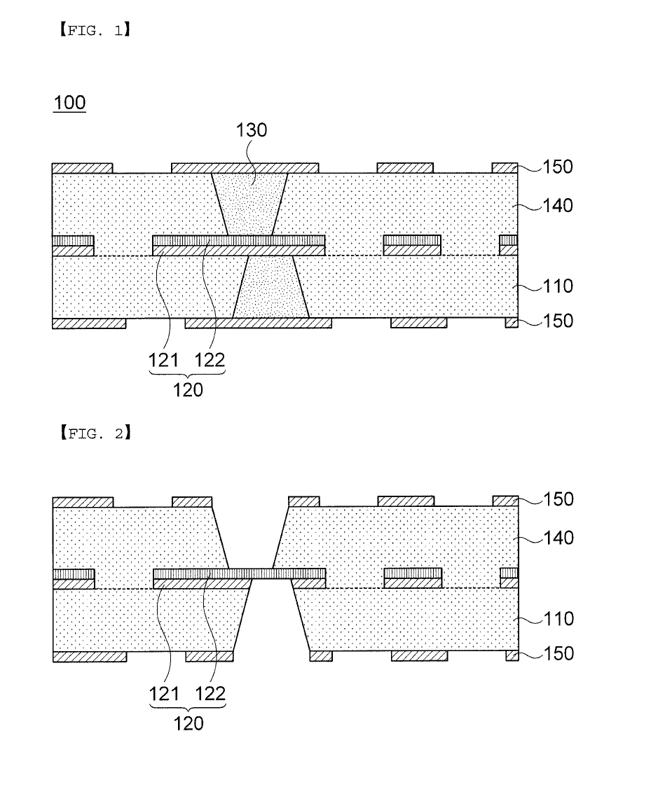

FIG. 1 is a cross-sectional view of a printed circuit board according to the present invention. Additionally, constitutions in the drawings are not necessarily drawn according to the reduced scale. For example, sizes of some constitutions in the drawings may be exaggerated as compared with the other constitutions for better comprehension of the present invention.

Referring to FIG. 1, a printed circuit board 100 according to the present invention may include an insulating layer 110, a circuit layer 120, and a via electrode 130.

The insulating layer 110 protects the circuit layer 120 and secures interlayer insulating property, and may be formed by using an appropriate resin insulator in consideration of the insulating property, heat resistance, moisture resistance, and the like. For example, the insulating layer may be formed by using a thermo-hardening resin such as an epoxy resin, a thermoplastic resin such as polyimide, or a resin (prepreg) impregnated with a reinforcing agent such as a glass fiber or an inorganic filler, but is not particularly limited thereto.

The circuit layer 120 is a signal line through which an electric signal with various devices (for example, semiconductor chips) mounted on the printed circuit board is transmitted. The circuit layer 120 may be plated on the insulating layer 110 in a predetermined pattern shape by employing a subtractive method, an additive method, a semi-additive method, or the like, which is well known in this field.

Here, the circuit layer 120 is characterized by being constituted in a structure where different kinds of metal layers having different thermal conductivities are laminated.

Specifically, the circuit layer 120 may be constituted in a structure where a first metal layer 121 and a second metal layer 122 are laminated, the second metal layer 122 having lower thermal conductivity than the first metal layer 121. Although FIG. 1 shows that the first metal layer 121 is positioned below the second metal layer 122 based on the lamination direction, this shows only one of several exemplary embodiments, and in the present invention, the first metal layer 121 and the second metal layer 122 may be laminated in an arbitrary order.

As described above, the circuit layer 120 is a signal line for transmitting the electric signal line therethrough. The circuit layer 120 needs to be formed of a metal material having excellent conductivity, and thus, the first metal layer 121 may be formed of a copper (Cu) material, which satisfies these conditions, generally has a low unit cost, and is easily patterned.

Therefore, the second metal layer 122 is preferably formed of a metal material having lower thermal conductivity than copper (Cu). For example, the second metal layer 122 may be formed of a metal selected from the group consisting of gold (Au), platinum (Pt), palladium (Pd), zinc (Zn), tin (Sn), indium (In), aluminum (Al), nickel (Ni), and an alloy thereof.

Table 1 below shows thermal conductivities of the foregoing metal materials. In the case where the first metal layer 121 and the second metal layer 122 are formed of the foregoing metal materials, the circuit layer 120 may be formed in a structure where a metal having lower thermal conductivity than copper (Cu) is plated on an upper surface (or a lower surface) of a copper (Cu) layer. A first type of circuit layer recited below denotes the circuit layer in FIG. 1.

TABLE 1

| Metal Material | Thermal Conductivity (W/(m · k)) |
|---|---|
| Copper (Cu) | 401 |
| Gold (Au) | 318 |
| Palladium (Pd) | 71.8 |
| Zinc (Zn) | 116 |
| Tin (Sn) | 66.8 |
| Platinum (Pt) | 71.6 |
| Indium (In) | 81.8 |
| Aluminum (Al) | 237 |
| Nickel (Ni) | 90.9 |

Meanwhile, the printed circuit board 100 of the present invention may further include a build-up insulating layer 140 covering the circuit layer 120.

The build-up insulating layer 140 may be formed of the same material as the insulating layer 110, and may be formed by a conventional deposition method or a solvent process, for example, spin coating, dip coating, doctor blading, screen printing, inkjet printing, thermal transferring, or the like, which is a method well known in the art.

An outer layer circuit pattern 150 of a single metal layer may be formed on an upper surface of the build-up insulating layer 140. The outer layer circuit pattern 150 may be operated as a signal transmission line with respect to the semiconductor chip, or some of the outer layer circuit patterns 150 may be used as pads through which wire bonding or flip chip bonding for connection with a semiconductor chip is implemented.

The via electrode 130 is formed at a predetermined position in the insulating layer 110 or the build-up insulating layer 140, to penetrate through an inside of the insulating layer 110 or the build-up insulating layer 140. Both end portions of the via electrode 130 are connected to the circuit layer 120 and the outer layer circuit pattern 150, and thus, the circuit layer 120 is electrically connected to the outer layer circuit pattern 150 through the via electrode 130.

This via electrode 130 may be filling-plated by using any one or a combination of electroless plating, electroplating, screen printing, sputtering, evaporation, ink-jetting, and dispensing.

Prior to this, a via hole is formed by performing a drilling process on a predetermined position in the insulating layer 110 or the build-up insulating layer 140. Here, in order to form a via hole having a fine diameter, the drilling process may be performed by using laser but not mechanical drilling.

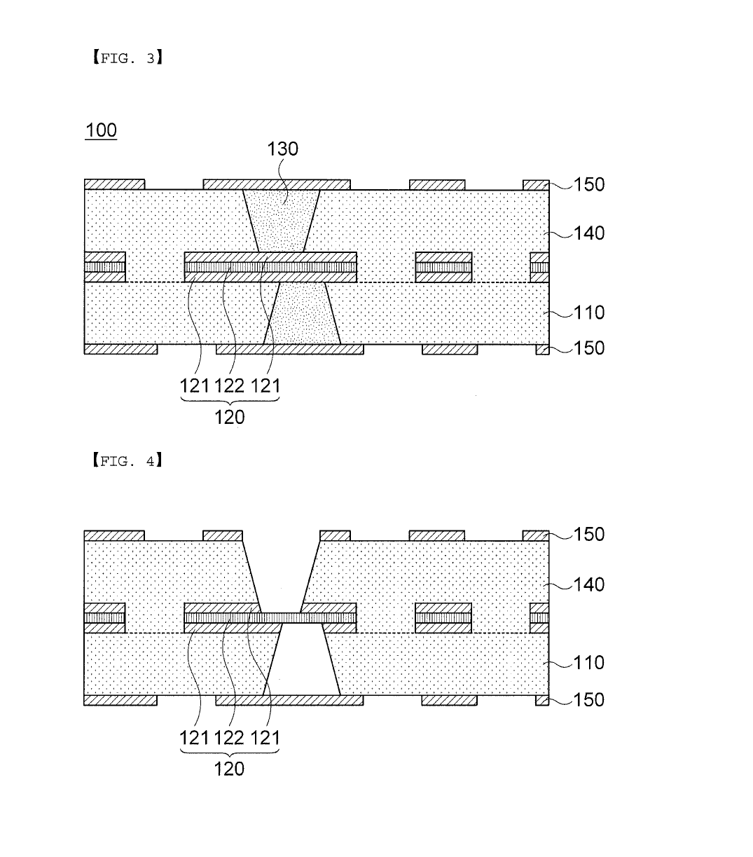

At the time of using the laser, even a circuit layer in the existing printed circuit board is at a risk of being penetrated due to high heat of the laser light. However, in the present invention, as described above, the circuit layer 120 is formed in a structure where different kinds of first and second metal layers 121 and 122 having different thermal conductivities are laminated, and the thermal conductivity of the second metal layer 122 is relatively lower than that of the first metal layer 121. Hence, as shown in FIG. 2, even though the first metal layer 121 is damaged due to the heat of the laser light, the second metal layer 122 is maintained intactly due to low thermal conductivity thereof, and thus, the circuit layer 120 is not at a risk of being entirely penetrated.

In addition, the circuit layer 120 can be formed thinly due to low thermal conductivity of the second metal layer 122, and thus, according to the present invention, a light, thin, short, and small type printed circuit board may be realized.

Specifically, the circuit layer 120 may have a thickness of 10 to 12 μm. The foregoing range is determined in consideration of thermal conductivities of the respective metal materials constituting the first and second metal layers 121 and 122 and thicknesses of the respective metal layers. Usually, as thermal conductivity of the metal material constituting the second metal layer 122 is lower and the second metal layer 122 is relatively thicker than the first metal layer 121, the overall thickness of the circuit layer 120 is smaller.

In addition, in order to generally reduce the risk of the circuit layer being penetrated at the time of forming the via hole, a copper foil on the insulating layer is removed (a window is opened) and then the laser is irradiated on the insulating layer. However, in the present invention, as described above, since the risk of the circuit layer being penetrated is low, it is possible to directly perform laser irradiation without a separate window opening process. Therefore, the process yield can be increased and the productivity of product can be improved.

FIG. 3 is a cross-sectional view of a printed circuit board to which another type of circuit layer is applied. For reference, the same reference numerals between FIG. 1 and FIG. 3 denote the same constituents.

Referring to FIG. 3, a circuit layer 120 included in a printed circuit board 100 in FIG. 3 is formed in a structure where different kinds of metal layers having different thermal conductivities are laminated.

Specifically, the circuit layer 120 may be composed of first metal layers 121 at the upper and lower layers and a second metal layer 122 positioned between the first metal layers 121 at the upper and lower layers, the second metal layer 122 having lower thermal conductivity than the first metal layer 121. A second type of circuit layer recited below denotes the circuit layer in FIG. 3.

Like the first type of circuit layer, the first metal layer 121 may be formed of a copper (Cu) material having excellent conductivity and being easily patterned. The second metal layer 122 may be formed of a metal selected from the group consisting of gold (Au), platinum (Pt), palladium (Pd), zinc (Zn), tin (Sn), indium (In), aluminum (Al), nickel (Ni), and an alloy thereof, each of which has lower thermal conductivity than copper (Cu).

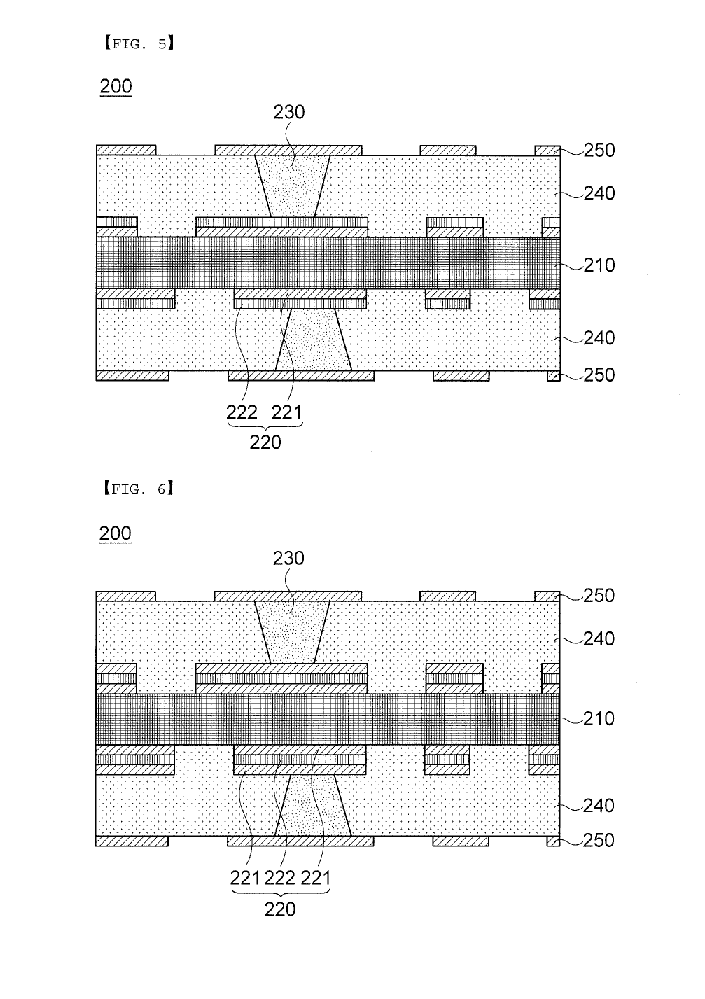

As such, the printed circuit board in FIG. 3 includes the circuit layer 120 where a metal having relatively lower thermal conductivity than copper (Cu) is plated between the copper layers at the upper and lower layers. Therefore, as shown in FIG. 4, even though the first metal layers 121 at the upper and lower layers are damaged due to irradiation of laser, the second metal layer 122 is maintained intactly due to low thermal conductivity thereof, and thus, the circuit layer 120 is not at a risk of being entirely penetrated.

FIG. 5 is a cross-sectional view of a printed circuit board according to another exemplary embodiment of the present invention, to which a first type circuit layer is applied.

Referring to FIG. 5, a printed circuit board 200 according to another exemplary embodiment of the present invention may be composed of a core insulating layer 210, a circuit layer 220 formed on one surface or both surfaces of the core insulating layer 210, an insulating layer 240 covering the circuit layer 220, and a via electrode 230 penetrating through the insulating layer 240 and being connected with the circuit layer 220.

The core insulating layer 210 may be a thermohardenable or thermoplastic polymer substrate, a ceramic substrate, an organic-inorganic complex material substrate, or a glass fiber impregnated substrate. In the case where the core insulating layer 210 contains a polymer resin, an epoxy based insulation resin or a polyimide based resin may be contained therein.

The insulating layer 240 may be further laminated by a build-up process according to the number of layers requested, and here, the circuit layer between the respective insulating layers 240 may be formed in the same structure as the circuit layer 220.

In addition, an outer layer circuit pattern 250 made of a single metal layer may be formed on an upper surface of the insulating layer 240 positioned at the outermost layer. The outer layer circuit pattern 250 is electrically connected with the circuit layer 220 through the via electrode 230.

The circuit layer 220 has the same structure as the first type of circuit layer 120 shown in FIG. 1. Therefore, the circuit layer 220 may be formed in a structure where a first metal layer 221 and a second metal layer 222 are stacked, the second metal layer 222 having lower thermal conductivity than the first metal layer 221.

Here, the second metal layer 222 is preferably positioned above the first metal layer 221 based on the lamination direction thereof. In this case, at the time of irradiation of laser for forming a via hole, the laser light reaches only to a surface of the second metal layer, and the heat by the laser light is not transferred to the first metal layer 221 due to low thermal conductivity of the second metal layer, whereby the risk of the circuit layer 220 being penetrated may be significantly decreased.

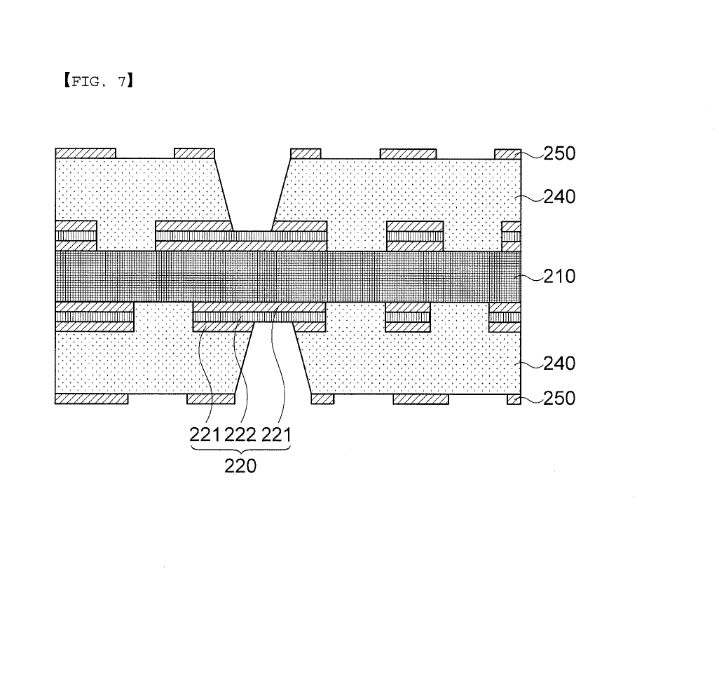

FIG. 6 is a cross-sectional view of a printed circuit board according to another exemplary embodiment of the present invention, to which a second type circuit layer is applied. For reference, the same reference numerals between FIG. 5 and FIG. 6 denote the same constituents.

In a printed circuit board 200 in FIG. 6, a circuit layer 220 has the same structure as the second type of circuit layer 120 shown in FIG. 3. Therefore, the circuit layer 220 may be composed of a first metal layer 221 at the upper and lower layers and a second metal layer 222 positioned between the first metal layers 221 at the upper and lower layers, the second metal layer 222 having lower thermal conductivity than the first metal layer 221.

In this case, as shown in FIG. 7, even though the first metal layers 221 at the upper layer is damaged due to irradiation of laser for forming a via hole, the second metal layer 222 and the first metal layer 221 at the lower layer are maintained intactly due to low thermal conductivity of the second metal layer 222, and thus, the circuit layer 220 is not at risk of being entirely penetrated.

As set forth above, since the printed circuit board according to the present invention includes a circuit layer having low thermal conductivity, the circuit layer is not at a risk of being penetrated at the time of irradiation of laser for forming a via hole, and thus, reliability of products can be improved.

Further, the thickness of the circuit layer can be decreased even without the risk of the circuit layer being penetrated, and thus the recent demand for the light, thin, short, and small type printed circuit board can be satisfied.

Further, since a laser is irradiated directly on an upper surface of the copper foil without separately opening a window, the effect of increasing productivity of products can be anticipated.

The present invention has been described in connection with what is presently considered to be practical exemplary embodiments. Although the exemplary embodiments of the present invention have been described, the present invention may be also used in various other combinations, modifications and environments. In other words, the present invention may be changed or modified within the range of concept of the invention disclosed in the specification, the range equivalent to the disclosure and/or the range of the technology or knowledge in the field to which the present invention pertains. The exemplary embodiments described above have been provided to explain the best state in carrying out the present invention. Therefore, they may be carried out in other states known to the field to which the present invention pertains in using other inventions such as the present invention and also be modified in various forms required in specific application fields and usages of the invention. Therefore, it is to be understood that the invention is not limited to the disclosed embodiments. It is to be understood that other embodiments are also included within the spirit and scope of the appended claims.

What is claimed is:

1. A printed circuit board, comprising:
an insulating layer;
a circuit layer formed on one surface of the insulating layer; and
a via electrode penetrating through the insulating layer and being connected with the circuit layer,
wherein the circuit layer is formed in a structure where different kinds of metal layers having different thermal conductivities are laminated.

2. The printed circuit board according to claim 1, wherein the circuit layer is composed of a first metal layer and a second metal layer, the second metal layer having lower thermal conductivity than the first metal layer.

3. The printed circuit board according to claim 1, wherein the first metal layer is formed of copper (Cu) and the second metal layer is formed of a metal selected from the group consisting of gold (Au), platinum (Pt), palladium (Pd), zinc (Zn), tin (Sn), indium (In), aluminum (Al), nickel (Na), and an alloy thereof.

4. The printed circuit board according to claim 1, wherein the circuit layer has a thickness of 10 to 12 μm.

5. The printed circuit board according to claim 1, further comprising an outer layer circuit pattern formed on the other surface of the insulating layer and electrically connected with the circuit layer through the via electrode.

6. The printed circuit board according to claim 1, further comprising:
a build-up insulating layer covering the circuit layer; and
another via electrode penetrating through the build-up insulating layer and being connected with the circuit layer.

7. The printed circuit board according to claim 1, wherein the circuit layer is composed of first metal layers at upper and lower layers and a second metal layer positioned between the first metal layers at upper and lower layers, the second metal layer having lower thermal conductivity than the first metal layer.

8. A printed circuit board, comprising;
a core insulating layer;
a circuit layer formed on one surface or both surfaces of the core insulating layer;
an insulating layer covering the circuit layer; and
a via electrode penetrating through the insulating layer and being connected with the circuit layer,
wherein the circuit layer is formed in a structure where different kinds of metal layers having different thermal conductivities are laminated.

9. The printed circuit board according to claim 8, wherein the circuit layer is composed of a first metal layer and a second metal layer, the second metal layer having lower thermal conductivity than the first metal layer.

10. The printed circuit board according to claim 9, wherein the second metal layer is positioned above the first metal layer based on a lamination direction thereof.

11. The printed circuit board according to claim 8, wherein the circuit layer is composed of first metal layers at upper and lower layers and a second metal layer positioned between the first metal layers at upper and lower layers, the second metal layer having lower thermal conductivity than the first metal layer.
